(19) United States
(12) Patent Application Publication
(10) Pub. No.: US 2024/0099093 A1
(43) Pub. Date: Mar. 21, 2024

(54) DISPLAY DEVICE AND METHOD OF MANUFACTURING THE SAME

(71) Applicant: Samsung Display Co., LTD., Yongin-si (KR)

(72) Inventors: HEE JUN YANG, Yongin-si (KR); WOO YONG SUNG, Yongin-si (KR); SEUNGYONG SONG, Yongin-si (KR)

(21) Appl. No.: 18/215,895

(22) Filed: Jun. 29, 2023

(30) Foreign Application Priority Data
Sep. 19, 2022 (KR) 10-2022-0117637

(51) Int. Cl. H10K 59/38; H10K 59/12; H10K 59/122

(52) U.S. Cl. CPC H10K 59/38; H10K 59/1201; H10K 59/122

(57) ABSTRACT

A display device include a substrate, a pixel electrode disposed on the substrate, a partition layer disposed on the substrate and defining an opening exposing at least a part of the pixel electrode, a light-emitting layer disposed on the pixel electrode within the opening of the partition layer, a common electrode disposed on the light-emitting layer within the opening of the partition layer, a capping layer disposed on the common electrode and the partition layer, and surrounding a side surface of the opening of the partition layer, and a color conversion pattern disposed on the capping layer within the opening of the partition layer.

This application claims priority to Korean Patent Application No. 10-2022-0117637, filed on Sep. 19, 2022, and all the benefits accruing therefrom under 35 U.S.C. § 119, the content of which in its entirety is herein incorporated by reference.

### BACKGROUND

### 1. Field

Embodiments relate to a display device and a method of manufacturing the same. More particularly, embodiments relate to a display device providing visual information and a method of manufacturing the same.

### 2. Description of the Related Art

A display device includes a light-emitting layer and a plurality of color conversion patterns. The light-emitting layer emits light, and the color conversion patterns convert colors of the light. Accordingly, the color conversion patterns may emit light having a color different from that of incident light.

The color conversion patterns may include quantum dots, and are divided into a red color conversion pattern, a green color conversion pattern, and a scattering pattern (or blue color conversion pattern). The red color conversion pattern embodies red pixels, the green color conversion pattern embodies green pixels, and the scattering pattern embodies blue pixels.

### SUMMARY

Embodiments provide a display device with improved display quality.

Embodiments provide a method of manufacturing the display device.

A display device in an embodiment includes a substrate, a pixel electrode disposed on the substrate, a partition layer disposed on the substrate and defining an opening exposing at least a part of the pixel electrode, a light-emitting layer disposed on the pixel electrode within the opening of the partition layer, a common electrode disposed on the light-emitting layer within the opening of the partition layer, a capping layer disposed on the common electrode and the partition layer, and surrounding a side surface of the opening of the partition layer, and a color conversion pattern disposed on the capping layer within the opening of the partition layer.

In an embodiment, the common electrode may contact the partition layer.

In an embodiment, the partition layer may include an inorganic layer disposed on the substrate, a first metal layer disposed on the inorganic layer, and a second metal layer disposed on the first metal layer.

In an embodiment, a side surface of the second metal layer adjacent to the opening may protrude compared to a side surface of the first metal layer adjacent to the opening.

In an embodiment, the display device may further include a pixel defining layer disposed on the partition layer and overlapping with the partition layer.

In an embodiment, the light-emitting layer may include a first light-emitting layer disposed on the pixel electrode within the opening, and a second light-emitting layer disposed on the partition layer and overlapping with the partition layer, in which the first light-emitting layer and the second light-emitting layer are spaced apart from each other.

In an embodiment, the capping layer may extend from a first surface of the common electrode to a first surface of the partition layer along the side surface of the opening of the partition layer, the first surface of the common electrode may be opposite to a second surface of the common electrode facing the substrate, and the first surface of the partition layer may be opposite to a second surface of the partition layer facing the substrate.

In an embodiment, the capping layer may include an inorganic material.

A method of manufacturing a display device in an embodiment includes forming a pixel electrode on a substrate, forming a preliminary partition layer on the substrate, forming a partition layer by defining an opening overlapping with the pixel electrode in the preliminary partition layer, forming a light-emitting layer on the pixel electrode within the opening of the partition layer, forming a common electrode on the light-emitting layer within the opening of the partition layer, forming a capping layer on the common electrode, the partition layer, and a side surface of the opening of the partition layer, and forming a color conversion pattern on the capping layer within the opening of the partition layer.

In an embodiment, the common electrode may contact the partition layer.

In an embodiment, the forming the preliminary partition layer may include forming a preliminary inorganic layer covering the pixel electrode on the substrate, forming a preliminary first metal layer on the preliminary inorganic layer, and forming a preliminary second metal layer on the preliminary first metal layer.

In an embodiment, the forming the partition layer may include defining a first sub-opening by dry etching the preliminary partition layer overlapping with the pixel electrode, and wet etching a side surface of the preliminary first metal layer exposed by the dry etching, and defining a second sub-opening overlapping with the first sub-opening by etching the preliminary inorganic layer overlapping with the pixel electrode.

In an embodiment, the second sub-opening may have an undercut structure.

In an embodiment, the capping layer may extend from a first surface of the common electrode to a first surface of the partition layer along the side surface of the opening of the partition layer, the first surface of the common electrode may be opposite to a second surface of the common electrode facing the substrate, and the first surface of the partition layer may be opposite to a second surface of the partition layer facing the substrate.

A method of manufacturing a display device in an embodiment includes forming a pixel electrode on a substrate, forming a preliminary partition layer on the substrate, forming a pixel defining layer defining a first opening on the preliminary partition layer, forming a partition layer by defining a second opening overlapping with the first opening in the preliminary partition layer, forming a light-emitting layer on the pixel electrode within the second opening of the partition layer, forming a common electrode on the light-emitting layer within the second opening of the partition layer, forming a capping layer on the common electrode, the partition layer, and a side surface of the second opening of the partition layer, and forming a color conversion pattern on the capping layer within the second opening of the partition layer.

In an embodiment, the common electrode may contact the partition layer.

In an embodiment, the forming the preliminary partition layer may include forming a preliminary inorganic layer covering the pixel electrode on the substrate, forming a preliminary first metal layer on the preliminary inorganic layer, and forming a preliminary second metal layer on the preliminary first metal layer.

In an embodiment, the forming the partition layer may include defining a first sub-opening overlapping with the first opening by dry etching the preliminary partition layer overlapping with the pixel electrode, and wet etching a side surface of the preliminary first metal layer exposed by the dry etching, and defining a second sub-opening overlapping with the first sub-opening by etching the preliminary inorganic layer overlapping with the pixel electrode.

In an embodiment, the second sub-opening may have an undercut structure.

In an embodiment, the method may further include removing the pixel defining layer, before the forming the capping layer.

In embodiments of a display device according to the disclosure, a light-emitting layer and a common electrode may be short-circuited for each pixel and sealed by a single-layer capping layer, thereby minimizing a permeation path, so that a growing dark spot may be improved. In addition, as a metal layer is disposed to surround a part of a side surface of a color conversion pattern, light emitted from the color conversion pattern is reflected, so that the light-emitting efficiency of the display device may be increased. In addition, a separate encapsulation process is unnecessary other than the capping layer deposition process, and a separate space is unnecessary for the color conversion pattern, so that a manufacturing process of the display device may be simplified. Thus, display quality and productivity of the display device may be improved.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a plan view for explaining an embodiment of a display device.

FIG. 2 is a cross-sectional view taken along line I-I′ of FIG. 1.

FIG. 3 is an enlarged cross-sectional view of area A of FIG. 2.

FIGS. 4, 5, 6, 7, 8, 9, 10, 11, 12, 13 and 14 are cross-sectional views for explaining a method of manufacturing the display device of FIG. 1.

FIG. 15 is a plan view for explaining another embodiment of a display device.

FIG. 16 is a cross-sectional view taken along line II-II′ in FIG. 15.

FIGS. 17, 18 and 19 are cross-sectional views for explaining a method of manufacturing the display device of FIG. 15.

FIG. 20 is a plan view for explaining another embodiment of a display device.

FIG. 21 is a cross-sectional view taken along line in FIG. 20.

FIGS. 22, 23, 24, 25, 26, 27, 28, 29 and 30 are cross-sectional views for explaining a method of manufacturing the display device of FIG. 20.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

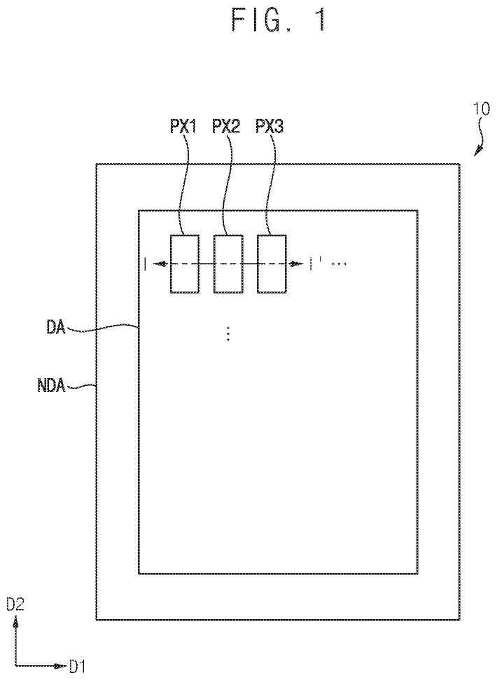

FIG. 1 is a plan view for explaining an embodiment of a display device.

Referring to FIG. 1, a display device 10 in an embodiment of the disclosure may include a display area DA and a non-display area NDA. The display area DA may be an area capable of generating light to display an image. The non-display area NDA may be an area that does not display an image. In addition, the non-display area NDA may surround at least a part of the display area DA. In an embodiment, the non-display area NDA may surround an entirety of the display area DA, for example.

A plurality of pixels emitting light may be disposed in the display area DA, and accordingly, an image may be displayed in the display area DA. The pixels may be arranged in a matrix form in a first direction D1 and a second direction D2 intersecting the first direction D1. However, the disclosure is not limited thereto, and pixels may be arranged in various other forms. In an embodiment, the second direction D2 may be perpendicular to the first direction D1, for example. Although FIG. 1 shows only first, second and third pixels PX1, PX2 and PX3 disposed in a part of the display area DA, the disclosure is not limited thereto.

The first, second and third pixels PX1, PX2 and PX3 may emit light of different colors from each other or substantially the same color as each other. In an embodiment, the first pixel PX1 may emit red light, the second pixel PX2 may emit blue light, and the third pixel PX3 may emit green light, for example. However, the disclosure is not limited thereto, and the color of light emitted from the first, second and third pixels PX1, PX2 and PX3 may be variously changed.

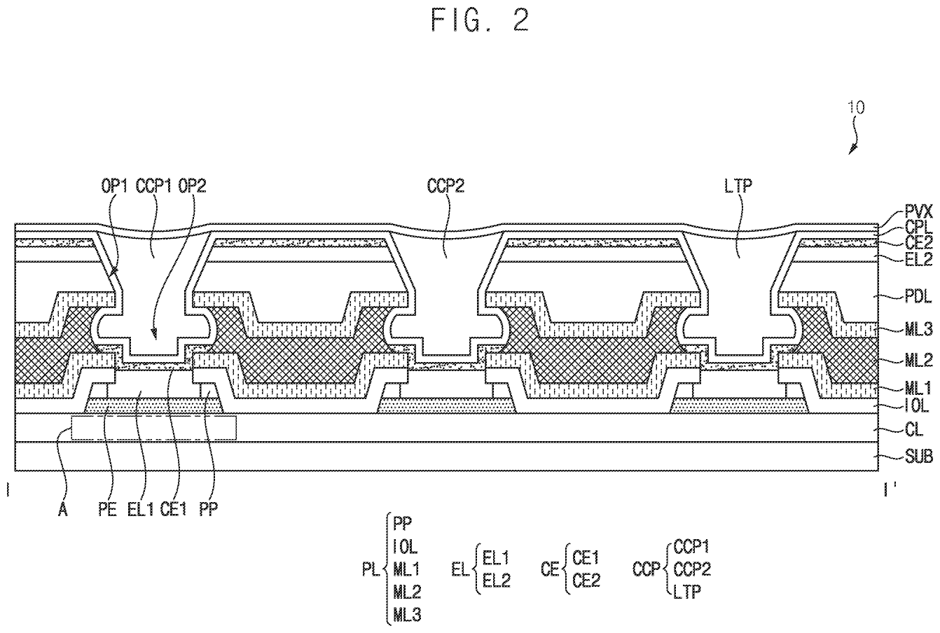

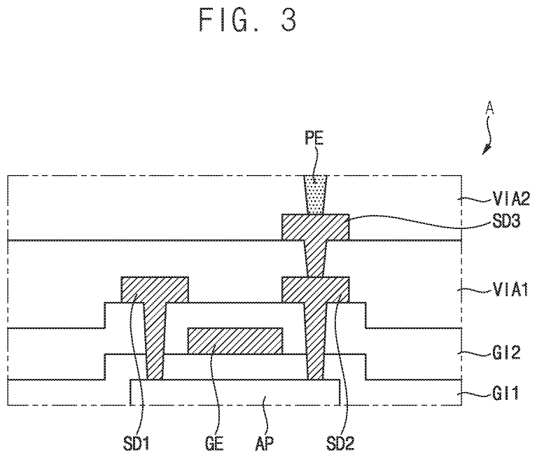

FIG. 2 is a cross-sectional view taken along line I-I′ of FIG. 1. FIG. 3 is an enlarged cross-sectional view of area A of FIG. 2. In an embodiment, FIGS. 2 and 3 are cross-sectional views showing an embodiment of the display area DA of the display device 10 of FIG. 1, for example.

In an embodiment, FIG. 3 is an enlarged cross-sectional view showing a circuit layer CL in the first pixel PX1, for example. Although FIG. 3 does not show cross-sectional structures of circuit layers CL in the second pixel PX2 and the third pixel PX3, the cross-sectional structures of the circuit layers CL in the second pixel PX2 and the third pixel PX3 may be substantially the same as the cross-sectional structure of the circuit layer CL in the first pixel PX1.

Referring to FIGS. 2 and 3, the display device 10 in an embodiment of the disclosure may include a substrate SUB, a circuit layer CL, a pixel electrode PE, a partition layer PL, a pixel defining layer PDL, a light-emitting layer EL, a common electrode CE, a capping layer CPL, a color conversion pattern CCP, and a passivation layer PVX.

The substrate SUB may include a transparent material or an opaque material. In embodiments, the material that may be used as the substrate SUB may include glass, quartz, plastic, or the like. These may be used individually or in any combinations with each other.

The circuit layer CL may include an active pattern AP, a first insulating layer GI1, a gate electrode GE, a second insulating layer GI2, a first connection electrode SD1, a second connection electrode SD2, a first via-insulation layer VIA1, a third connection electrode SD3, and a second via-insulation layer VIA2.

The active pattern AP may be disposed on the substrate SUB. In an embodiment, the active pattern AP may include a silicon semiconductor material or an oxide semiconductor material. In embodiments, the silicon semiconductor material that may be used as the active pattern AP may include amorphous silicon, polycrystalline silicon, or the like. In embodiments, the oxide semiconductor material that may be used as the active pattern AP may include indium gallium zinc oxide (“IGZO”), indium tin zinc oxide (“ITZO”), or the like. These may be used individually or in any combinations with each other. The active pattern AP may have a source area, a drain area, and a channel area disposed between the source area and the drain area.

The first insulating layer GI1 may be disposed on the substrate SUB, and may cover the active pattern AP. In an embodiment, the first insulating layer GI1 may include an inorganic insulating material. In embodiments, the inorganic insulating material that may be used as the first insulating layer GI1 may include silicon oxide, silicon nitride, silicon oxynitride, or the like. These may be used individually or in any combinations with each other.

The gate electrode GE may be disposed on the first insulating layer GI1. The gate electrode GE may overlap with the channel area of the active pattern AP. In an embodiment, the gate electrode GE may include a conductive material. In embodiments, the conductive material that may be used as the gate electrode GE may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), or the like. These may be used individually or in any combinations with each other.

The second insulating layer GI2 may be disposed on the first insulating layer GI1, and may cover the gate electrode GE. In an embodiment, the second insulating layer GI2 may include an inorganic insulating material. In embodiments, the inorganic insulating material that may be used as the second insulating layer GI2 may include silicon oxide, silicon nitride, silicon oxynitride, or the like. These may be used individually or in any combinations with each other.

The first connection electrode SD1 and the second connection electrode SD2 may be disposed on the second insulating layer GI2. In an embodiment, each of the first and second connection electrodes SD1 and SD2 may include a conductive material. In embodiments, the conductive material that may be used for each of the first and second connection electrodes SD1 and SD2 may include aluminum, platinum, palladium, silver, magnesium, gold, nickel, neodymium, iridium, chromium, lithium, calcium, molybdenum, titanium, tungsten, copper, or the like. These may be used individually or in any combinations with each other.

The first connection electrode SD1 may contact the source area of the active pattern AP through contact hole defined in the first insulating layer GI1 and the second insulating layer GI2. The second connection electrode SD2 may contact the drain area of the active pattern AP through contact hole defined in the first insulating layer GI1 and the second insulating layer GI2.

The first via-insulation layer VIA1 may be disposed on the second insulating layer GI2, and may cover the first and second connection electrodes SD1 and SD2. In an embodiment, the first via-insulation layer VIA1 may include an organic insulating material. In embodiments, the organic insulating material that may be used as the first via-insulation layer VIA1 may include photoresist, polyacrylic resin, polyimide-based resin, acrylic resin, or the like. These may be used individually or in any combinations with each other.

The third connection electrode SD3 may be disposed on the first via-insulation layer VIA1. In an embodiment, the third connection electrode SD3 may include a conductive material. In embodiments, the conductive material that may be used as the third connection electrode SD3 may include aluminum, platinum, palladium, silver, magnesium, gold, nickel, neodymium, iridium, chromium, lithium, calcium, molybdenum, titanium, tungsten, copper, or the like. These may be used individually or in any combinations with each other. The third connection electrode SD3 may contact the second connection electrode SD2 through a contact hole defined in the first via-insulation layer VIA1.

The second via-insulation layer VIA2 may be disposed on the first via-insulation layer VIA1, and may cover the third connection electrode SD3. In an embodiment, the second via-insulation layer VIA2 may include an organic insulating material. In embodiments, the organic insulating material that may be used as the second via-insulation layer VIA2 may include photoresist, polyacrylic resin, polyimide-based resin, acrylic resin, or the like. These may be used individually or in any combinations with each other. The pixel electrode PE may contact the third connection electrode SD3 through a contact hole defined in the second via-insulation layer VIA2.

The pixel electrode PE may be disposed on the circuit layer CL. The pixel electrode PE may include a conductive material. In embodiments, the conductive material that may be used as the pixel electrode PE may include aluminum, platinum, palladium, silver, magnesium, gold, nickel, neodymium, iridium, chromium, lithium, calcium, molybdenum, titanium, tungsten, copper, indium tin oxide (ITO), indium zinc oxide (IZO), or the like. These may be used individually or in any combinations with each other.

The partition layer PL may be disposed on the circuit layer CL. In the partition layer PL, a second opening OP2 exposing at least a part of the pixel electrode PE may be defined. In the partition layer PL, a plurality of second openings OP2 may be defined. In an embodiment, the partition layer PL may include a protection pattern PP, an inorganic layer IOL, a first metal layer ML1, a second metal layer ML2, and a third metal layer ML3.

The protection pattern PP may be disposed on the pixel electrode PE. Specifically, the protection pattern PP may be disposed on opposite sides of an upper surface of the pixel electrode PE in a cross-sectional view. In an embodiment, the protection pattern PP may include metal oxide. In an embodiment, the protection pattern PP may include IZO, for example.

The inorganic layer IOL may be disposed on the circuit layer CL. A part of the inorganic layer IOL may overlap with parts of the protection pattern PP and the pixel electrode PE. In an embodiment, the inorganic layer IOL may include silicon oxide.

The first metal layer ML1, the second metal layer ML2, and the third metal layer ML3 may be sequentially disposed on the inorganic layer IOL. In an embodiment, side surfaces of the first metal layer ML1 and the third metal layer ML3 adjacent to the second opening OP2 may protrude further than a side surface of the second metal layer ML2 adjacent to the second opening OP2.

In an embodiment, the first metal layer ML1 and the third metal layer ML3 may include a material different from a material of the second metal layer ML2. In an embodiment, the first metal layer ML1 and the third metal layer ML3 may include titanium (Ti), and the second metal layer ML2 may include aluminum (Al), for example. However, the disclosure is not limited thereto.

In an embodiment, the first metal layer ML1 may have a thickness greater than or equal to a thickness of the third metal layer ML3 in a direction (e.g., vertical direction in FIG. 2) perpendicular to a plane defined by the first and second directions D1 and D2.

However, the disclosure is not limited thereto, and the first metal layer ML1 may be omitted.

The pixel defining layer PDL may be disposed on the partition layer PL and overlap with the partition layer PL. In an embodiment, in the pixel defining layer PDL, a first opening OP1 overlapping with the second opening OP2 may be defined. In the pixel defining layer PDL, a plurality of first openings OP1 may be defined. The pixel defining layer PDL may include an organic insulating material. In embodiments, the organic insulating material that may be used as the pixel defining layer PDL may include photoresist, polyacrylic resin, polyimide-based resin, acrylic resin, or the like. These may be used individually or in any combinations with each other.

The light-emitting layer EL may be disposed on the pixel electrode PE and the partition layer PL. The light-emitting layer EL may include a first light-emitting layer EL1 and a second light-emitting layer EL2. In an embodiment, the first light-emitting layer EL1 may be disposed on the pixel electrode PE in the second opening OP2, for example. The second light-emitting layer EL2 may be disposed on the pixel defining layer PDL and overlap with the partition layer PL. In an embodiment, the first light-emitting layer EL1 and the second light-emitting layer EL2 may be spaced apart from each other. The light-emitting layer EL may include or consist of an organic material, and emit light of a preset color. In an embodiment, the light-emitting layer EL may emit blue light, for example. However, the disclosure is not limited thereto.

The common electrode CE may be disposed on the light-emitting layer EL. The common electrode CE may include a first common electrode CE1 and a second common electrode CE2. In an embodiment, the first common electrode CE1 may be disposed on the first light-emitting layer EL1 in the second opening OP2, for example. The second common electrode CE2 may be disposed on the second light-emitting layer EL2 and overlap with the partition layer PL. In an embodiment, the first common electrode CE1 and the second common electrode CE2 may be spaced apart from each other. The common electrode CE may include metal. In embodiments, the metal that may be used as the common electrode CE may include lithium, calcium, aluminum, silver, magnesium, or the like. These may be used individually or in any combinations with each other.

In an embodiment, the first common electrode CE1 may contact the partition layer PL. In an embodiment, the first common electrode CE1 may contact the first metal layer ML1 and the second metal layer ML2, for example. Accordingly, the first common electrodes CE1 disposed in the second openings OP2 may be electrically connected to each other through the partition layer PL.

The capping layer CPL may be disposed on the common electrode CE and the partition layer PL, and may surround side surfaces of the first opening OP1 and the second opening OP2. In an embodiment, the capping layer CPL may extend from an upper surface of the first common electrode CE1 to an upper surface of the partition layer PL along the side surfaces of the first opening OP1 and the second opening OP2. In an embodiment, the capping layer CPL may extend from the upper surface of the first common electrode CE1 to an upper surface of the second common electrode CE2 along the side surfaces of the first opening OP1 and the second opening OP2, for example. The capping layer CPL may come into direct contact with the upper surface of the second common electrode CE2. In an embodiment, the capping layer CPL may include an inorganic material.

The color conversion pattern CCP may be disposed on the capping layer CPL in the first opening OP1 and the second opening OP2. In an embodiment, the color conversion pattern CCP may include a first color conversion pattern CCP1, a second color conversion pattern CCP2 and a transmission pattern LTP. The first and second color conversion patterns CCP1 and CCP2 may convert light emitted from the light-emitting layer EL into light having a predetermined wavelength.

The first color conversion pattern CCP1 may include first quantum dots excited by the light emitted from the light-emitting layer EL to emit light of a first color. In addition, the first color conversion pattern CCP1 may further include first scattering particles and a first photosensitive polymer in which the first scattering particles are dispersed. In an embodiment, the first color conversion pattern CCP1 may convert the light emitted from the light-emitting layer EL into light of the first color. In an embodiment, when the light emitted from the light-emitting layer EL passes through the first color conversion pattern CCP1, red light may be emitted, for example. However, the disclosure is not limited thereto.

The second color conversion pattern CCP2 may include second quantum dots excited by the light emitted from the light-emitting layer EL to emit light of a second color. In addition, the second color conversion pattern CCP2 may further include second scattering particles and a second photosensitive polymer in which the second scattering particles are dispersed. In an embodiment, the second color conversion pattern CCP2 may convert the light emitted from the light-emitting layer EL into light of the second color. In an embodiment, when the light emitted from the light-emitting layer EL passes through the second color conversion pattern CCP2, green light may be emitted, for example. However, the disclosure is not limited thereto.

The transmission pattern LTP may include third scattering particles and a third photosensitive polymer in which the third scattering particles are dispersed. In an embodiment, the transmission pattern LTP may transmit the light emitted from the light-emitting layer EL. In an embodiment, when the light emitted from the light-emitting layer EL passes through the transmission pattern LTP, blue light may be emitted, for example. However, the disclosure is not limited thereto.

The passivation layer PVX may be disposed on the capping layer CPL, and may cover the color conversion pattern CCP. The passivation layer PVX may include an inorganic material and/or an organic material. In embodiments, the inorganic material that may be used as the passivation layer PVX may include silicon oxide, silicon nitride, silicon oxynitride, or the like. In embodiments, the organic material that maybe used as the passivation layer PVX may include photoresist, polyacrylic resin, polyimide-based resin, acrylic resin, or the like. These may be used individually or in any combinations with each other.

In the display device 10 according to the disclosure, the light-emitting layer EL and the common electrode CE are short-circuited for each pixel and sealed by the single-layer capping layer CPL, thereby minimizing a permeation path, so that a growing dark spot may be improved. In addition, when a metal layer is disposed to surround a part of a side surface of the color conversion pattern CCP, the light emitted from the color conversion pattern CCP is reflected, so that the light-emitting efficiency of the display device 10 may be increased. In addition, a separate encapsulation process is unnecessary other than the capping layer CPL deposition process, and a separate space is unnecessary for the color conversion patterns CCP, so that a manufacturing process of the display device 10 may be simplified. Thus, display quality and productivity of the display device 10 may be improved.

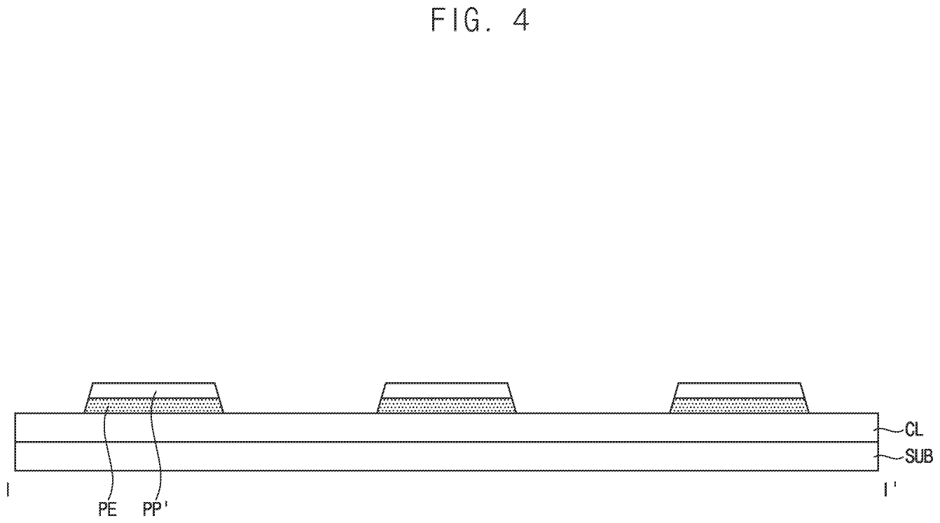

FIGS. 4, 5, 6, 7, 8, 9, 10, 11, 12, 13 and 14 are cross-sectional views for explaining a method of manufacturing the display device of FIG. 1.

Referring to FIG. 4, the circuit layer CL may be formed on a substrate SUB. The pixel electrode PE and a preliminary protection pattern PP′ may be formed on the circuit layer CL. The preliminary protection pattern PP′ may cover the entirety of the upper surface of the pixel electrode PE. The preliminary protection pattern PP′ may include the same material as that of the protection pattern PP.

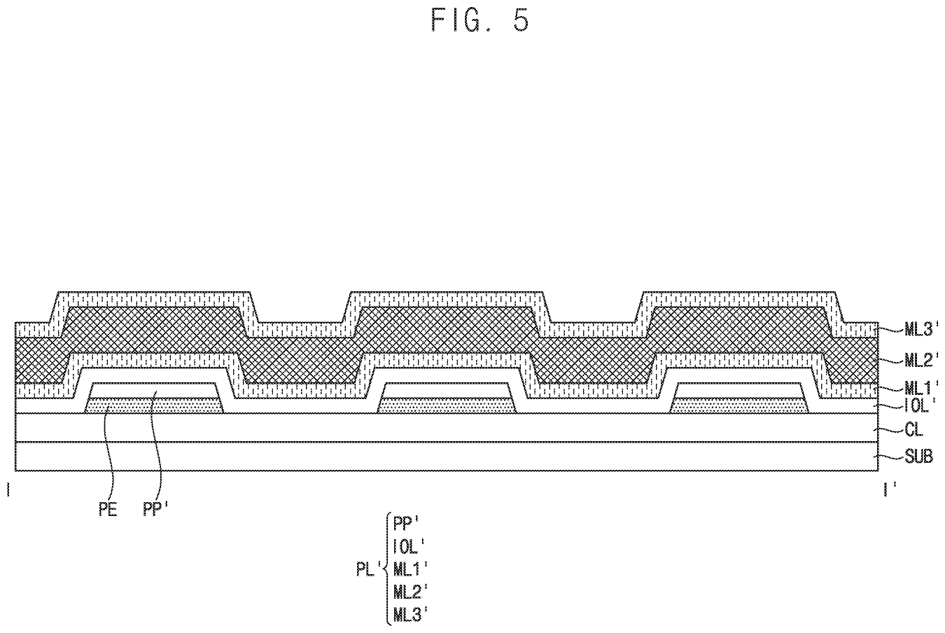

Referring to FIG. 5, a preliminary partition layer PL′ may be formed on the circuit layer CL to cover the pixel electrode PE and the preliminary protection pattern PP′. In an embodiment, a preliminary inorganic layer IOL′ covering the pixel electrode PE and the preliminary protection pattern PP′ may be formed on the substrate SUB, a preliminary first metal layer ML1′ may be formed on the preliminary inorganic layer IOL′, a preliminary second metal layer ML2′ may be formed on the preliminary first metal layer ML1′, and a preliminary third metal layer ML3′ may be formed on the preliminary second metal layer ML2′, so that the preliminary partition layer PL′ may be formed.

The preliminary inorganic layer IOL′, the preliminary first metal layer ML1′, the preliminary second metal layer ML2′, and the preliminary third metal layer ML3′ may include the same materials as the inorganic layer IOL, the first metal layer ML1, the second metal layer ML2, and the third metal layer ML3, respectively.

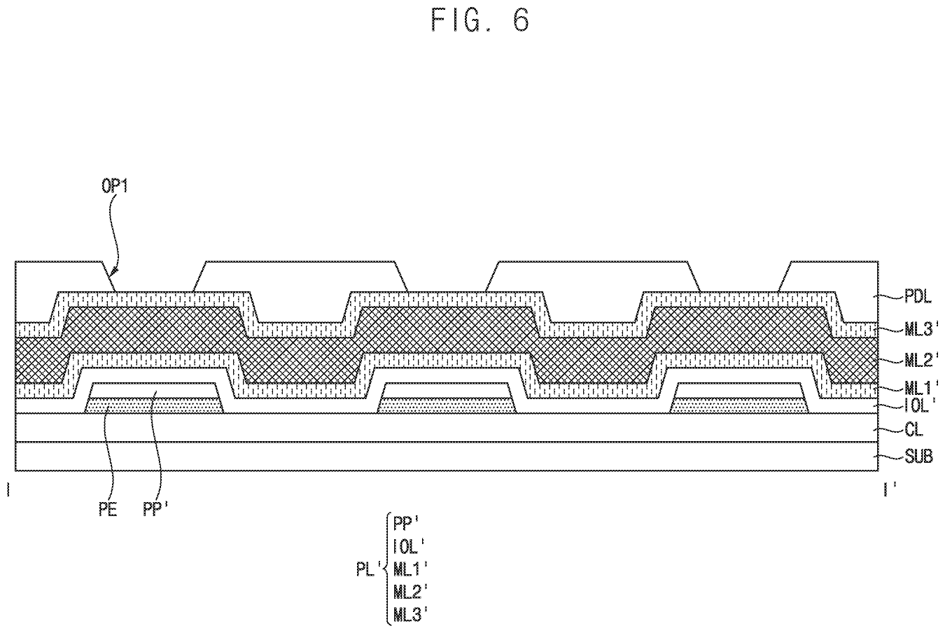

Referring to FIG. 6, the pixel defining layer PDL may be formed on the preliminary partition layer PL′. In the pixel defining layer PDL, the first opening OP1 overlapping with the pixel electrode PE and exposing a part of the preliminary partition layer PL′ may be formed.

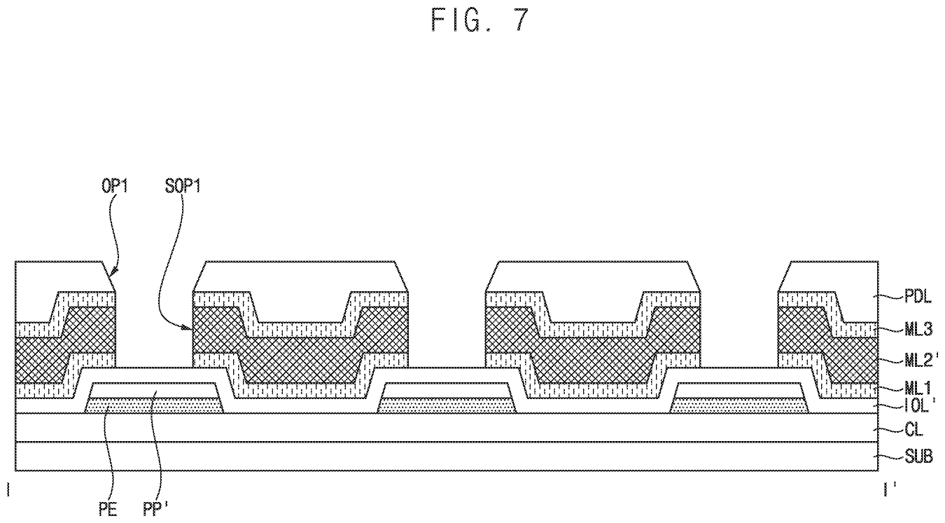

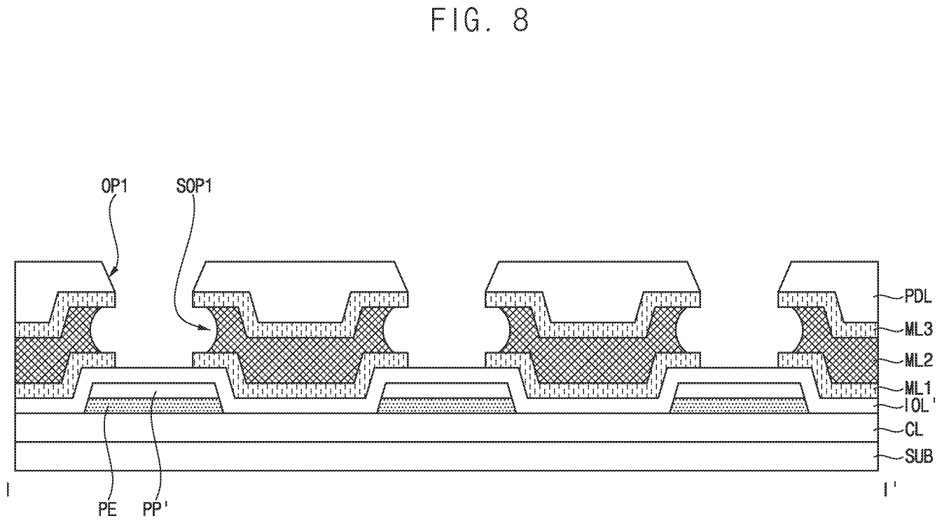

Referring to FIGS. 7 and 8, a first sub-opening SOP1 overlapping with the first opening OP1 and exposing a part of the preliminary inorganic layer IOL′ may be formed.

In an embodiment, the preliminary partition layer PL′ overlapping with the pixel electrode PE may be partially removed by dry etching, for example. Specifically, the preliminary first metal layer ML1′, the preliminary second metal layer ML2′, and the preliminary third metal layer ML3′ overlapping with the pixel electrode PE may be partially removed by the dry etching. A side surface of the preliminary second metal layer ML2′ exposed by the dry etching may be partially removed by wet etching, so that the first sub-opening SOP1 may be formed. Accordingly, the first sub-opening SOP1 may have a shape recessed inward.

In an embodiment, the preliminary first metal layer ML1′, the preliminary second metal layer ML2′, and the preliminary third metal layer ML3′ may be partially removed, so that the first metal layer ML1, the second metal layer ML2, and the third metal layer ML3 may be formed, respectively.

In this case, since the preliminary first metal layer ML1′ covers the entirety of the upper surface of the preliminary inorganic layer IOL′, the preliminary inorganic layer IOL′ may not be removed by the dry etching. In other words, the preliminary first metal layer ML1′ may protect the preliminary inorganic layer IOL′ from the dry etching.

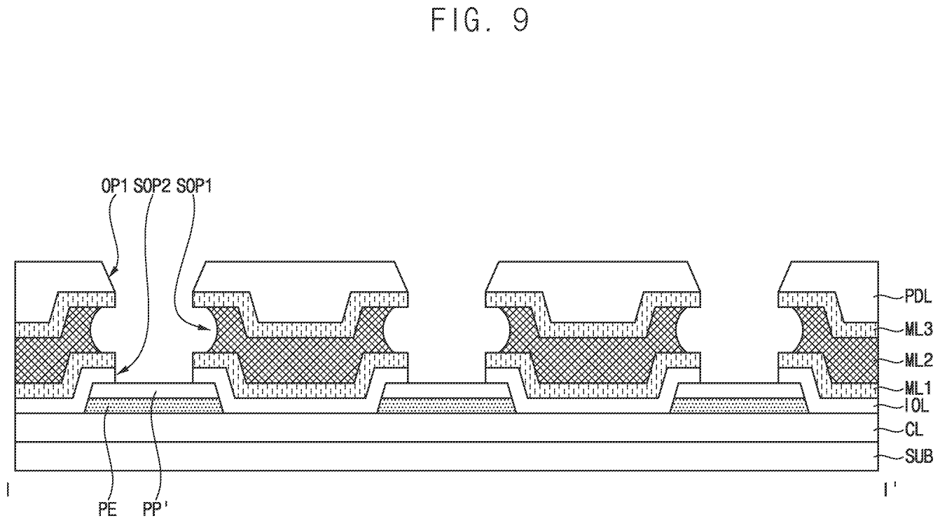

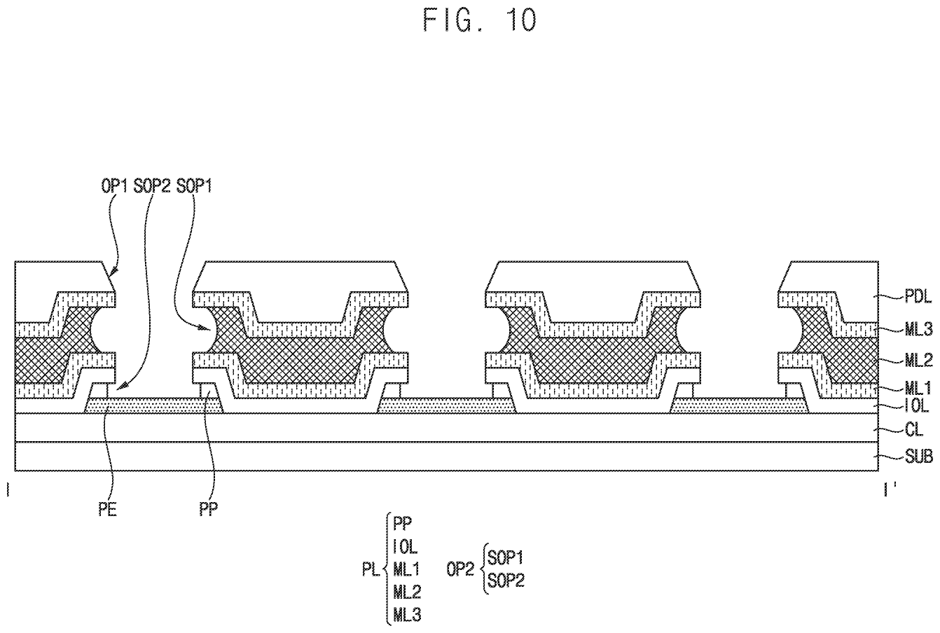

Referring to FIGS. 9 and 10, a second sub-opening SOP2 overlapping with the first sub-opening SOP1 and exposing a part of the pixel electrode PE may be formed.

In an embodiment, the preliminary inorganic layer IOL′ overlapping with the pixel electrode PE may be partially removed by dry etching, for example. The preliminary protection pattern PP′ exposed by the dry etching may be partially removed by wet etching, so that the second sub-opening SOP2 may be formed. Accordingly, the second sub-opening SOP2 may have an undercut structure.

In an embodiment, the preliminary inorganic layer IOL′ and the preliminary protection pattern PP′ may be partially removed, so that the inorganic layer IOL and the protection pattern PP may be formed, respectively. In addition, as the second sub-opening SOP2 overlapping with the first sub-opening SOP1 is formed, the second opening OP2 may be formed. Accordingly, the partition layer PL defining the second opening OP2 may be formed.

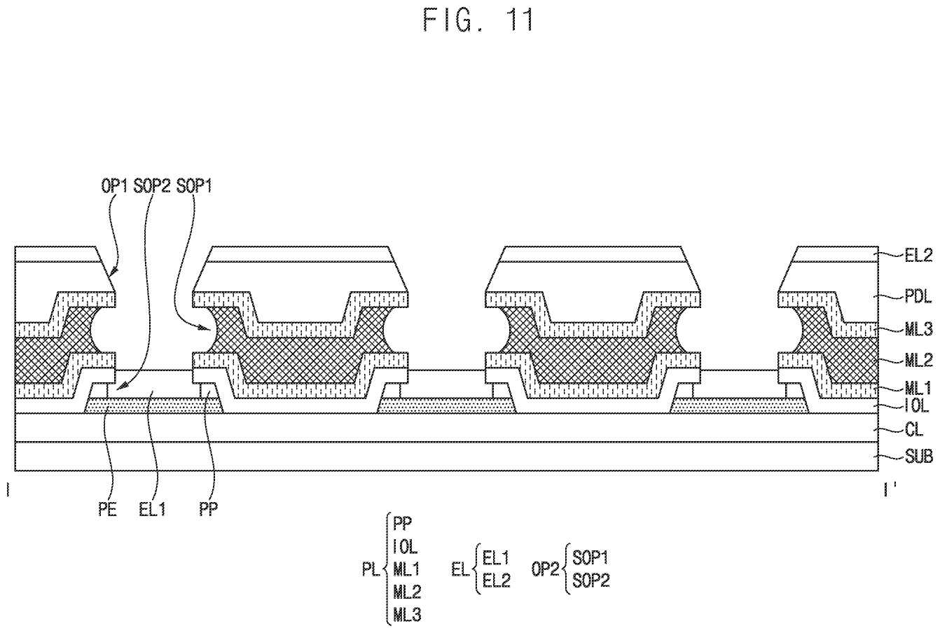

Referring to FIG. 11, the light-emitting layer EL may be formed on the pixel electrode PE and the partition layer PL. The light-emitting layer EL may include the first light-emitting layer EL1 and the second light-emitting layer EL2. In an embodiment, the first light-emitting layer EL1 may be formed on the pixel electrode PE in the second opening OP2. Accordingly, the first light-emitting layer EL1 in the second opening OP2 may fill a space of the undercut structure of the second sub-opening SOP2. In addition, the second light-emitting layer EL2 may be formed on the partition layer PL. In an embodiment, the second light-emitting layer EL2 may be formed on the pixel defining layer PDL, for example.

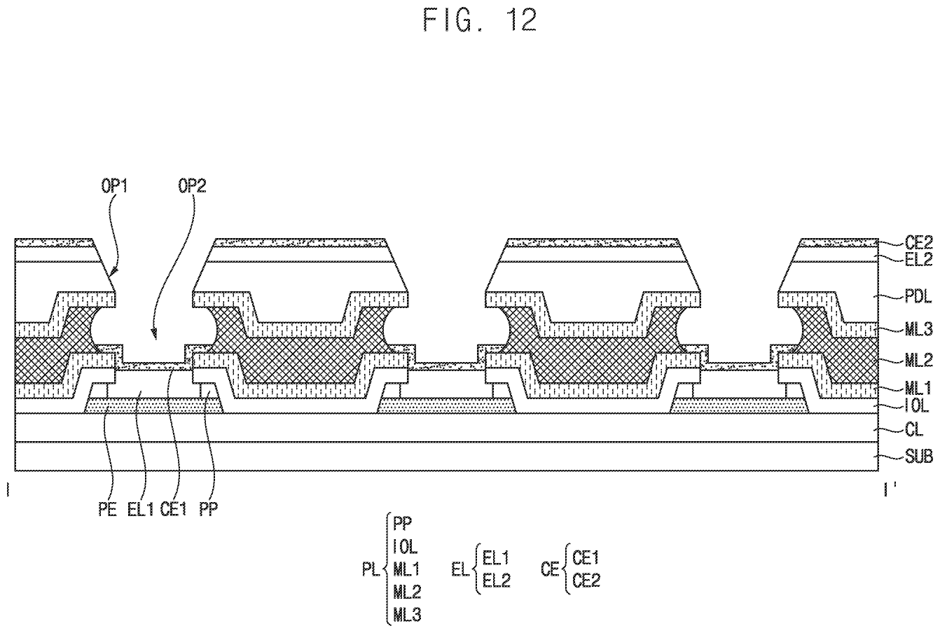

Referring to FIG. 12, the common electrode CE may be formed on the light-emitting layer EL. The common electrode CE may include the first common electrode CE1 and the second common electrode CE2. In an embodiment, the first common electrode CE1 may be formed on the first light-emitting layer EL1 in the second opening OP2. Accordingly, the first common electrode CE1 may contact the partition layer PL. In addition, the second common electrode CE2 may be formed on the partition layer PL. In an embodiment, the second common electrode CE2 may be formed on the second light-emitting layer EL2, for example.

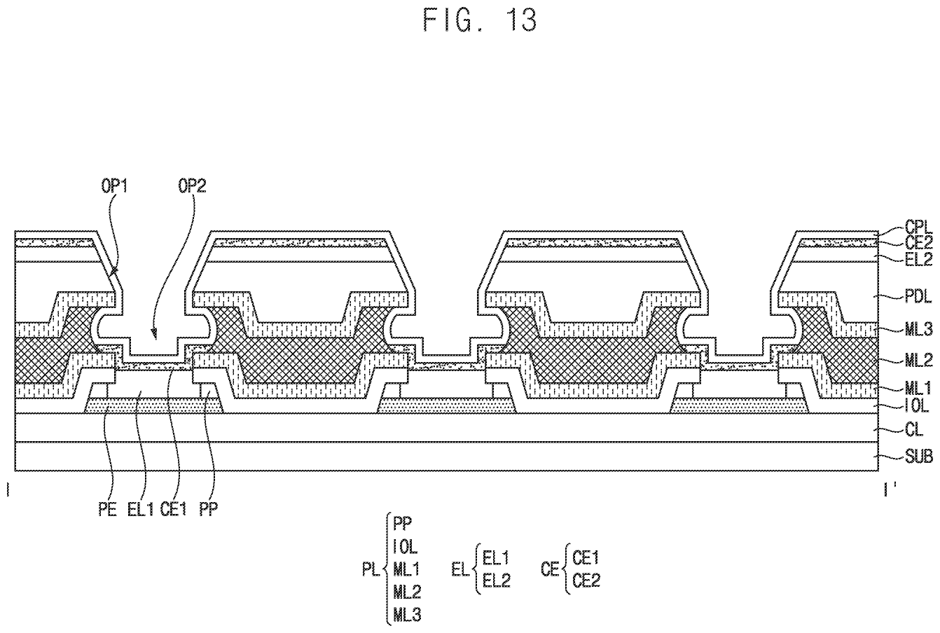

Referring to FIG. 13, the capping layer CPL may be formed on the common electrode CE, the partition layer PL, and the side surface of the first opening OP1 and the side surface of the second opening OP2. In an embodiment, the capping layer CPL may extend from the upper surface of the first common electrode CE1 to the upper surface of the second common electrode CE2 along the side surfaces of the first opening OP1 and the second opening OP2. The capping layer CPL may come into direct contact with the upper surface of the second common electrode CE2.

In an embodiment, the capping layer CPL may be formed by chemical vapor deposition (“CVD”) and atomic layer deposition (“ALD”). Accordingly, the capping layer CPL may have a relatively uniform deposition thickness, so that high step coverage may be implemented even with the single-layer capping layer CPL.

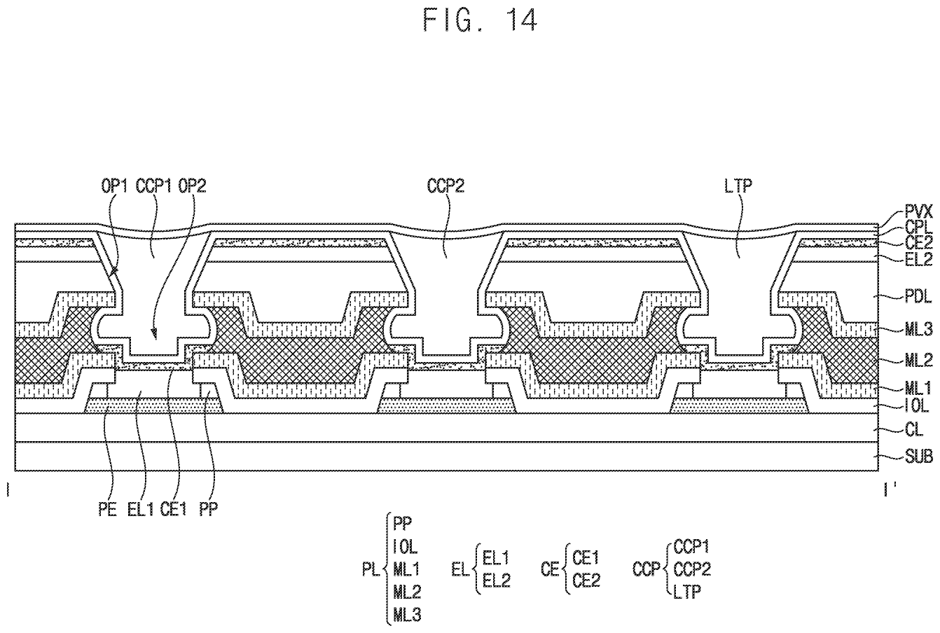

Referring to FIG. 14, the color conversion pattern CCP may be formed on the capping layer CPL in the first opening OP1 and the second opening OP2. In an embodiment, the color conversion pattern CCP may include the first color conversion pattern CCP1, the second color conversion pattern CCP2, and the transmission pattern LTP. In an embodiment, the color conversion pattern CCP may be formed by an inkjet process, for example.

The passivation layer PVX may be formed on the capping layer CPL. The passivation layer PVX may cover the color conversion pattern CCP.

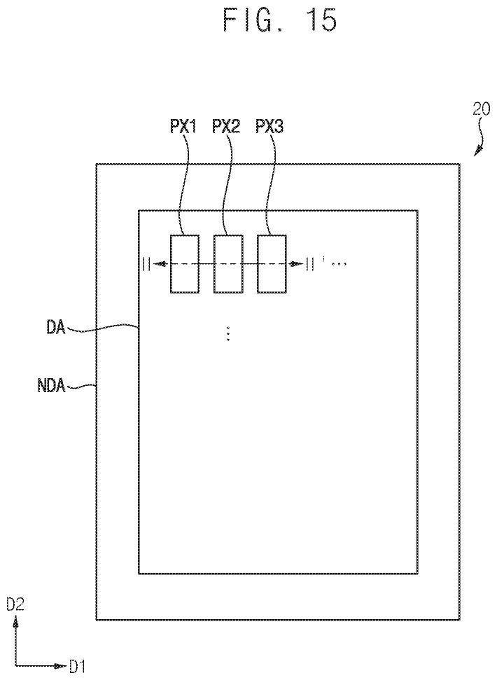

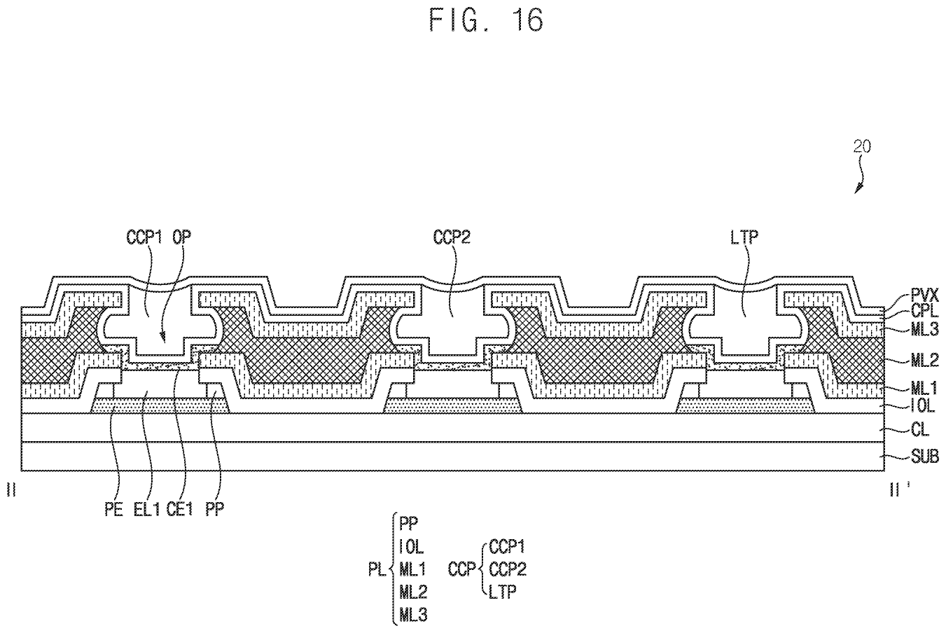

FIG. 15 is a plan view for explaining another embodiment of a display device. FIG. 16 is a cross-sectional view taken along line II-II′ in FIG. 15.

Hereinafter, the description overlapping with that of the display device 10 described with reference to FIG. 1 will be omitted or simplified.

Referring to FIGS. 15 and 16, a display device 20 in another embodiment of the disclosure may include a substrate SUB, a circuit layer CL, a pixel electrode PE, a partition layer PL, a first light-emitting layer EL1, a first common electrode CE1, a capping layer CPL, a color conversion pattern CCP, and a passivation layer PVX.

The partition layer PL may be disposed on the circuit layer CL. In the partition layer PL, an opening OP exposing at least a part of the pixel electrode PE may be defined. In the partition layer PL, a plurality of openings OP may be defined. In an embodiment, the partition layer PL may include a protection pattern PP, an inorganic layer IOL, a first metal layer ML1, a second metal layer ML2, and a third metal layer ML3.

The first light-emitting layer EL1 may be disposed on the pixel electrode PE. In an embodiment, the first light-emitting layer EL1 may be disposed on the pixel electrode PE in the opening OP.

The first common electrode CE1 may be disposed on the first light-emitting layer EL 1. In an embodiment, the first common electrode CE1 may be disposed on the first light-emitting layer EL1 in the opening OP.

The capping layer CPL may be disposed on the first common electrode CE1 and the partition layer PL, and may surround a side surface of the opening OP. In an embodiment, the capping layer CPL may extend from an upper surface of the first common electrode CE1 to an upper surface of the partition layer PL along the side surface of the opening OP. The capping layer CPL may come into direct contact with the upper surface of the partition layer PL.

The color conversion pattern CCP may be disposed on the capping layer CPL in the opening OP. In an embodiment, the color conversion pattern CCP may include a first color conversion pattern CCP1, a second color conversion pattern CCP2, and a transmission pattern LTP.

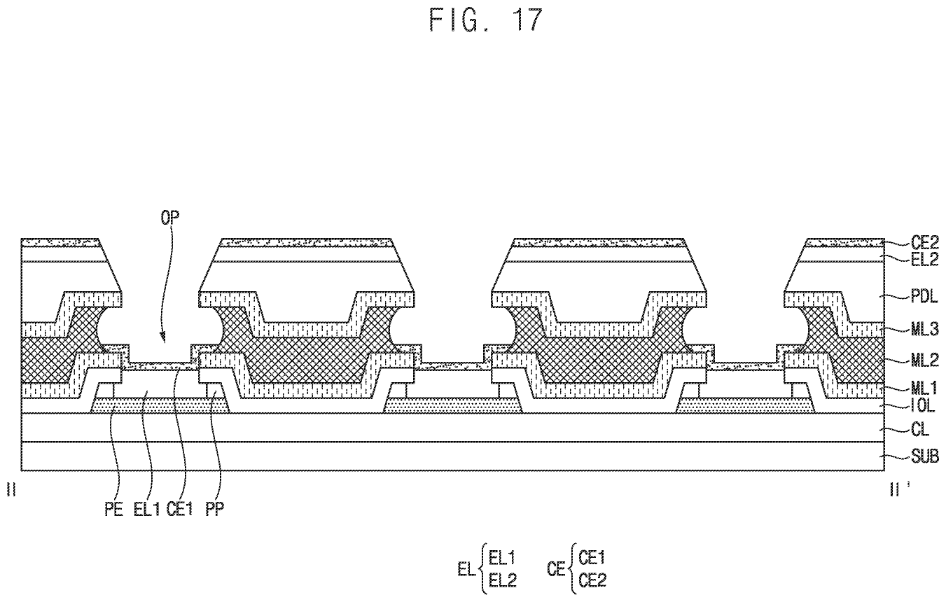

FIGS. 17, 18 and 19 are cross-sectional views for explaining a method of manufacturing the display device of FIG. 15. Hereinafter, the description overlapping with that of the method of manufacturing the display device 10 described with reference to FIGS. 4 to 14 will be omitted or simplified.

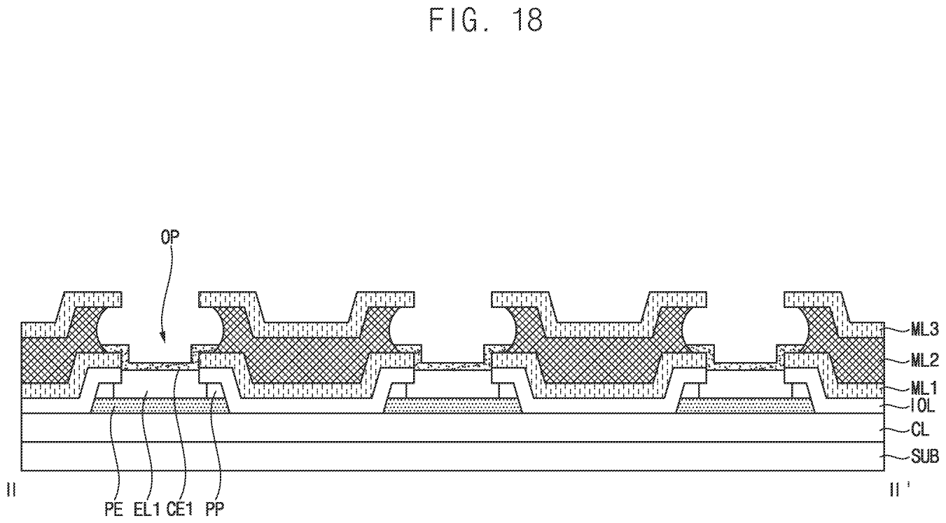

Referring to FIGS. 17 and 18, a pixel defining layer PDL may be formed on the partition layer PL. A light-emitting layer EL may be formed on the pixel electrode PE and the partition layer PL. The light-emitting layer EL may include the first light-emitting layer EL1 disposed on the pixel electrode PE in the opening OP, and a second light-emitting layer EL2 disposed on the pixel defining layer PDL and overlapping with the partition layer PL.

A common electrode CE may be formed on the light-emitting layer EL. The common electrode CE may include the first common electrode CE1 disposed on the first light-emitting layer EL1 in the opening OP, and a second common electrode CE2 disposed on the second light-emitting layer EL2 and overlapping the partition layer PL.

After the first common electrode CE1 and the second common electrode CE2 are formed, the pixel defining layer PDL may be removed. In an embodiment, the pixel defining layer PDL, the second light-emitting layer EL2, and the second common electrode CE2 may be removed.

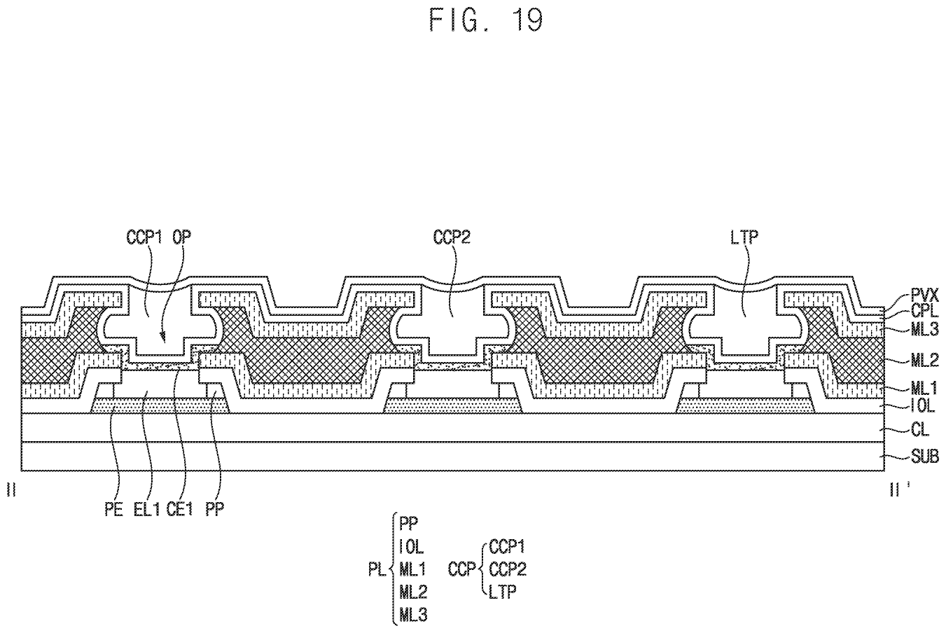

Referring to FIG. 19, the capping layer CPL may be formed on the first common electrode CE1, the partition layer PL and the side surface of the opening OP. In an embodiment, the capping layer CPL may extend from an upper surface of the first common electrode CE1 to an upper surface of the partition layer PL along the side surface of the opening OP. The capping layer CPL may come into direct contact with the upper surface of the partition layer PL.

The color conversion pattern CCP may be formed on the capping layer CPL in the opening OP. The passivation layer PVX may be formed on the capping layer CPL to cover the color conversion pattern CCP.

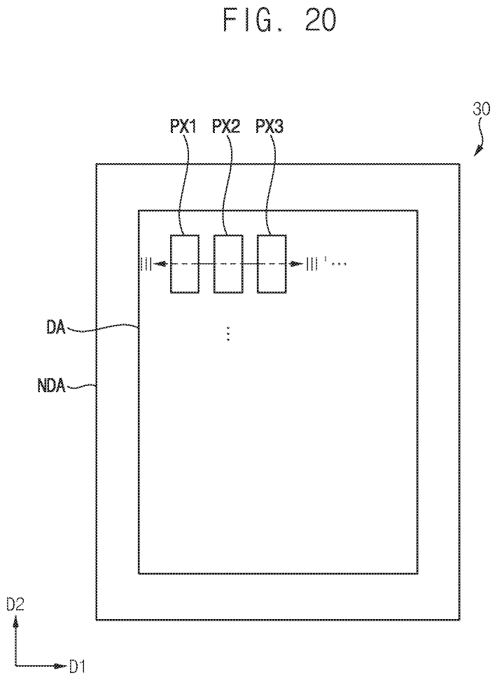

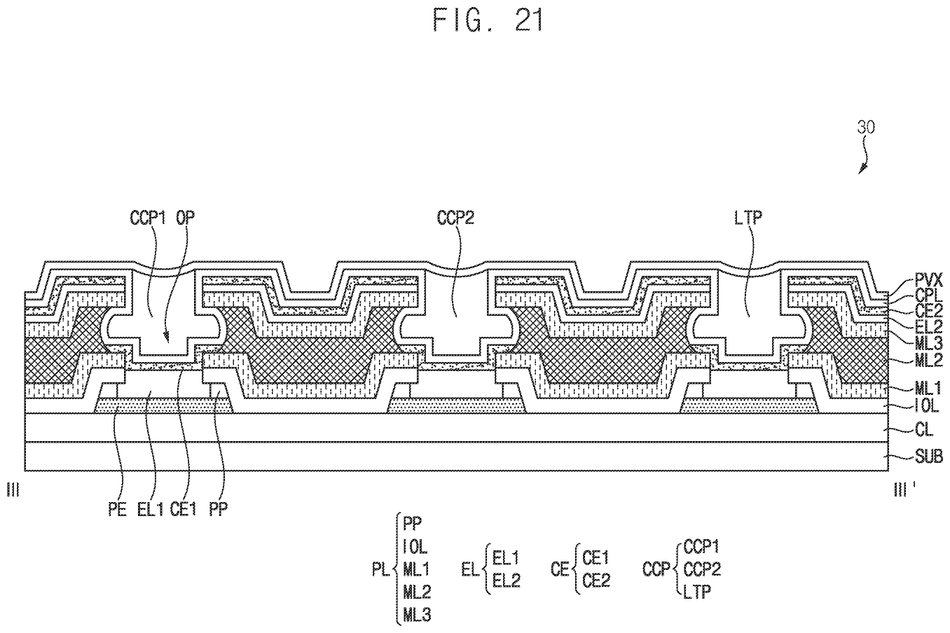

FIG. 20 is a plan view for explaining another embodiment of a display device. FIG. 21 is a cross-sectional view taken along line in FIG. 20.

Hereinafter, the description overlapping with that of the display device 10 described with reference to FIG. 1 will be omitted or simplified.

Referring to FIGS. 20 and 21, a display device 30 in another embodiment of the disclosure may include a substrate SUB, a circuit layer CL, a pixel electrode PE, a partition layer PL, a light-emitting layer EL, a common electrode CE, a capping layer CPL, a color conversion pattern CCP, and a passivation layer PVX.

The partition layer PL may be disposed on the circuit layer CL. In the partition layer PL, an opening OP exposing at least a part of the pixel electrode PE may be defined. In the partition layer PL, a plurality of openings OP may be defined. In an embodiment, the partition layer PL may include a protection pattern PP, an inorganic layer IOL, a first metal layer ML1, a second metal layer ML2, and a third metal layer ML3.

The light-emitting layer EL may be disposed on the pixel electrode PE and the partition layer PL. The light-emitting layer EL may include a first light-emitting layer EL1 and a second light-emitting layer EL2. In an embodiment, the first light-emitting layer EL1 may be disposed on the pixel electrode PE in the opening OP, for example. The second light-emitting layer EL2 may be disposed on the partition layer PL and overlap with the partition layer PL. In an embodiment, the first light-emitting layer EL1 and the second light-emitting layer EL2 may be spaced apart from each other.

The common electrode CE may be disposed on the light-emitting layer EL. The common electrode CE may include a first common electrode CE1 and a second common electrode CE2. In an embodiment, the first common electrode CE1 may be disposed on the first light-emitting layer EL1 in the opening OP, for example. The second common electrode CE2 may be disposed on the second light-emitting layer EL2 and overlap with the partition layer PL. In an embodiment, the first common electrode CE1 and the second common electrode CE2 may be spaced apart from each other.

The capping layer CPL may be disposed on the common electrode CE and the partition layer PL, and may surround a side surface of the opening OP. In an embodiment, the capping layer CPL may extend from an upper surface of the first common electrode CE1 to an upper surface of the partition layer PL along the side surface of the opening OP. In an embodiment, the capping layer CPL may extend from the upper surface of the first common electrode CE1 to the upper surface of the second common electrode CE2 along the side surface of the opening OP, for example. The capping layer CPL may come into direct contact with the upper surface of the second common electrode CE2.

The color conversion pattern CCP may be disposed on the capping layer CPL in the opening OP. In an embodiment, the color conversion pattern CCP may include a first color conversion pattern CCP1, a second color conversion pattern CCP2, and a transmission pattern LTP.

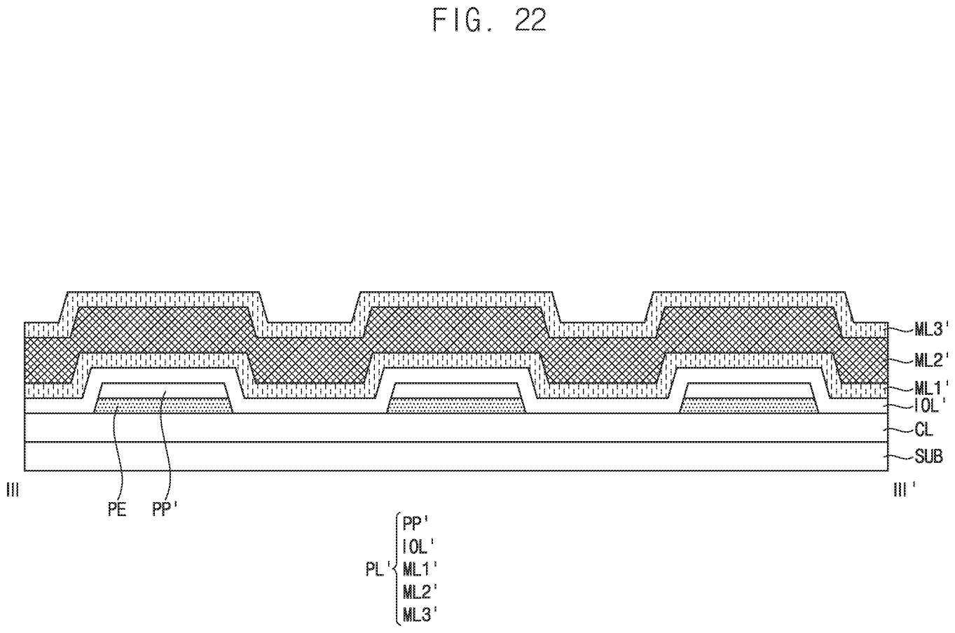

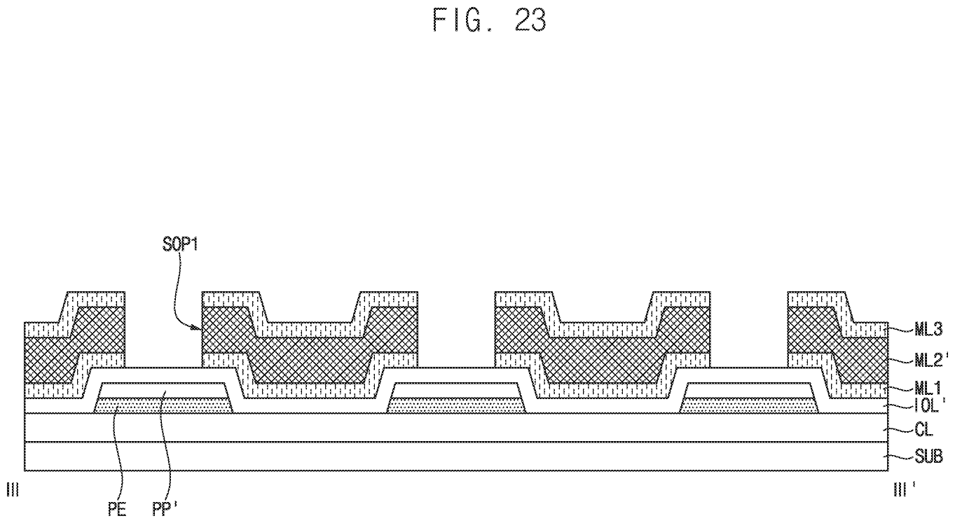

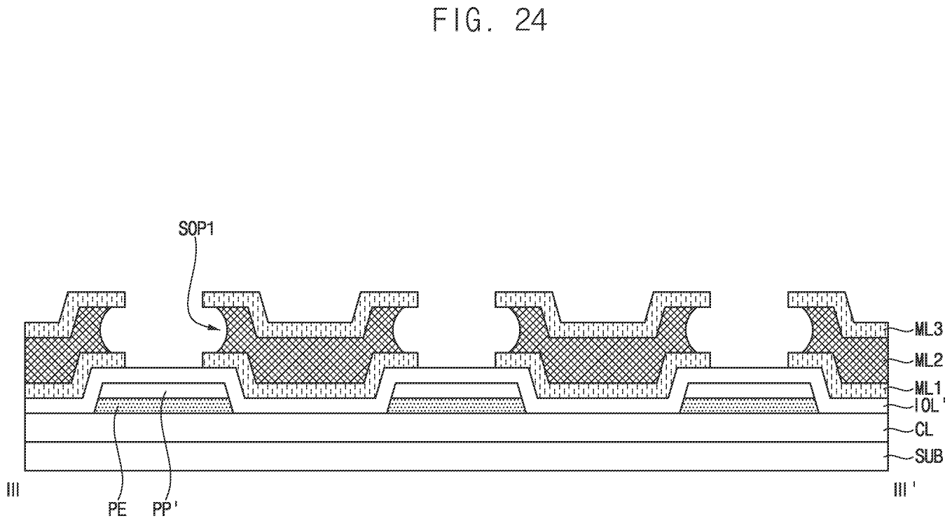

FIGS. 22, 23, 24, 25, 26, 27, 28, 29 and 30 are cross-sectional views for explaining a method of manufacturing the display device of FIG. 20. Hereinafter, the description overlapping with that of the method of manufacturing the display device 10 described with reference to FIGS. 4 to 14 will be omitted or simplified.

Referring to FIGS. 22, 23 and 24, a first sub-opening SOP1 overlapping with the pixel electrode PE and exposing a part of a preliminary inorganic layer IOL′ may be formed.

In an embodiment, a preliminary partition layer PL′ overlapping with the pixel electrode PE may be partially removed by dry etching. Specifically, a preliminary first metal layer ML1′, a preliminary second metal layer ML2′, and a preliminary third metal layer ML3′ overlapping with the pixel electrode PE may be partially removed by the dry etching, for example. A side surface of the preliminary second metal layer ML2′ exposed by the dry etching may be partially removed by wet etching, so that the first sub-opening SOP1 may be formed.

In an embodiment, the preliminary first metal layer ML1′, the preliminary second metal layer ML2′, and the preliminary third metal layer ML3′ may be partially removed, so that a first metal layer ML1, a second metal layer ML2, and a third metal layer ML3 may be formed, respectively.

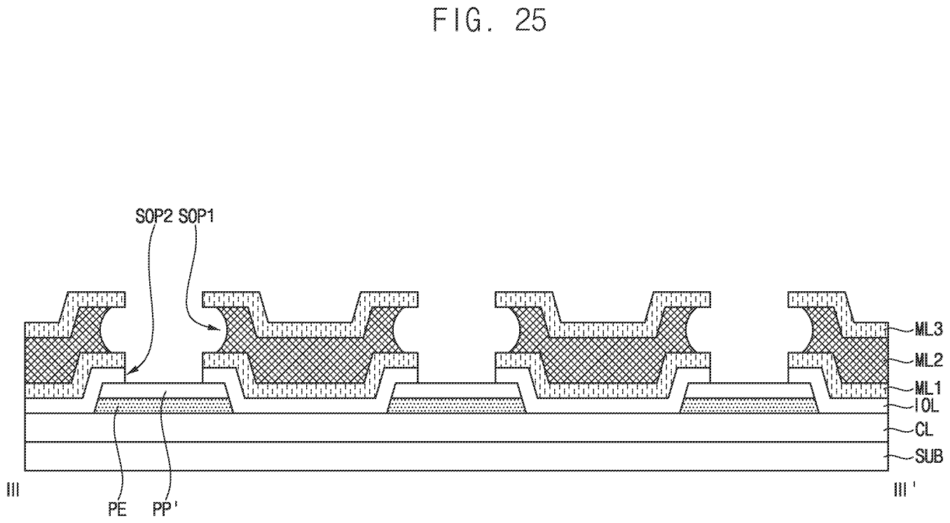

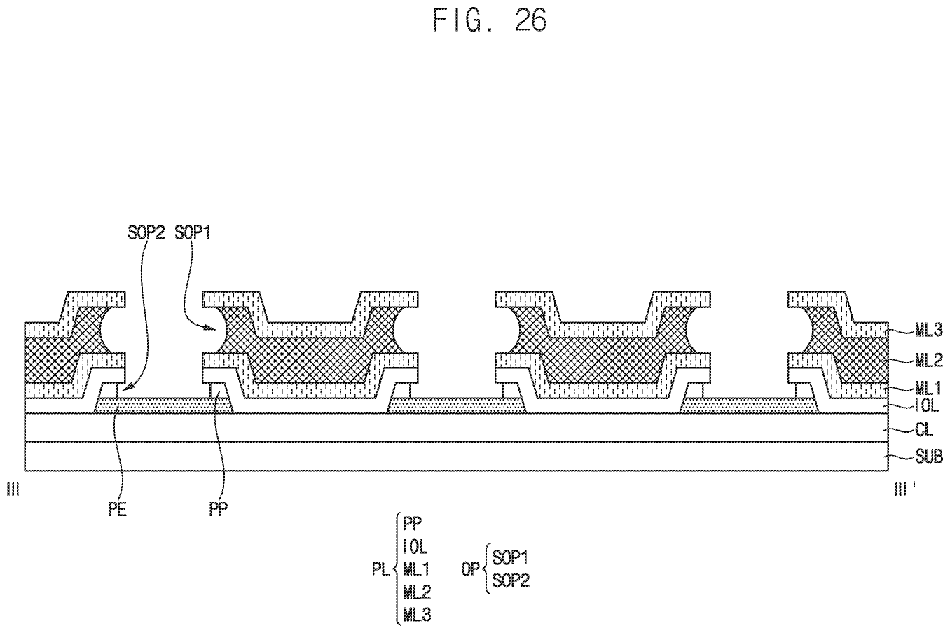

Referring to FIGS. 25 and 26, a second sub-opening SOP2 overlapping the first sub-opening SOP1 and exposing a part of the pixel electrode PE may be formed.

In an embodiment, the preliminary inorganic layer IOL′ overlapping with the pixel electrode PE may be partially removed by dry etching, for example. A preliminary protection pattern PP′ exposed by the dry etching may be partially removed by wet etching, so that the second sub-opening SOP2 may be formed. Accordingly, the second sub-opening SOP2 may have an undercut structure.

In an embodiment, the preliminary inorganic layer IOL′ and the preliminary protection pattern PP′ may be partially removed, so that an inorganic layer IOL and a protection pattern PP may be formed, respectively. In addition, when the second sub-opening SOP2 overlapping with the first sub-opening SOP1 is formed, the opening OP may be formed. Accordingly, the partition layer PL defining the opening OP may be formed.

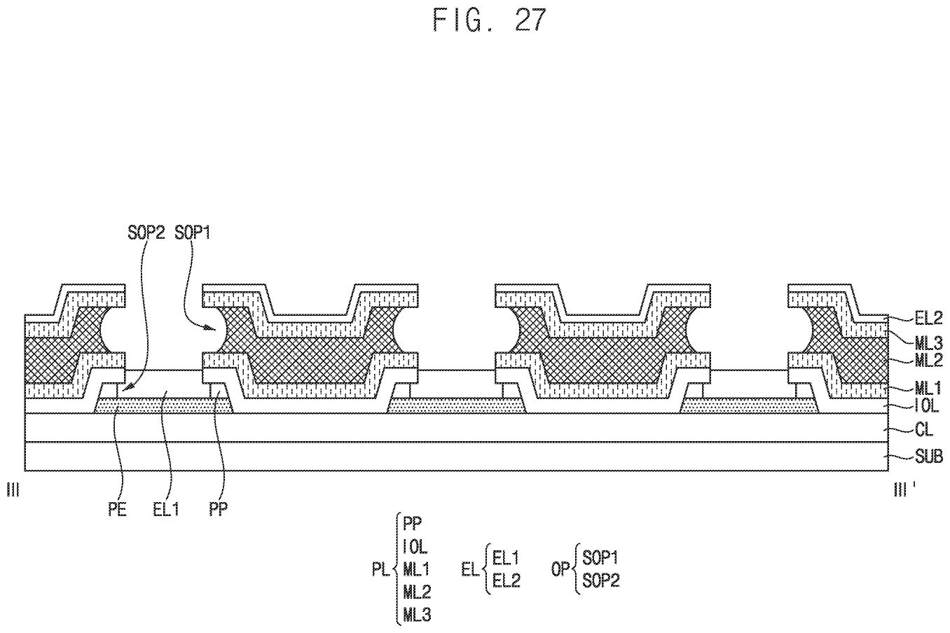

Referring to FIG. 27, the light-emitting layer EL may be formed on the pixel electrode PE and the partition layer PL. The light-emitting layer EL may include the first light-emitting layer EL1 and the second light-emitting layer EL2. In an embodiment, the first light-emitting layer EL1 may be formed on the pixel electrode PE in the opening OP. Accordingly, the first light-emitting layer EL1 in the opening OP may fill a space of the undercut structure of the second sub-opening SOP2. In addition, a second light-emitting layer EL2 may be formed on the partition layer PL.

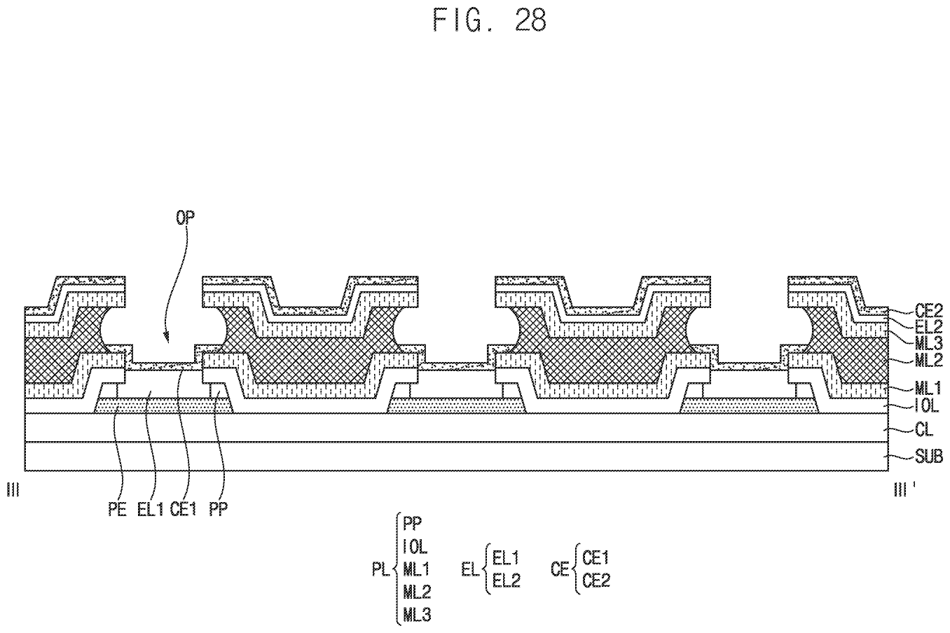

Referring to FIG. 28, the common electrode CE may be formed on the light-emitting layer EL. The common electrode CE may include the first common electrode CE1 and the second common electrode CE2. In an embodiment, the first common electrode CE1 may be formed on the first light-emitting layer EL1 in the opening OP. Accordingly, the first common electrode CE1 may contact the partition layer PL. In addition, the second common electrode CE2 may be formed on the partition layer PL. In an embodiment, the second common electrode CE2 may be formed on the second light-emitting layer EL2, for example.

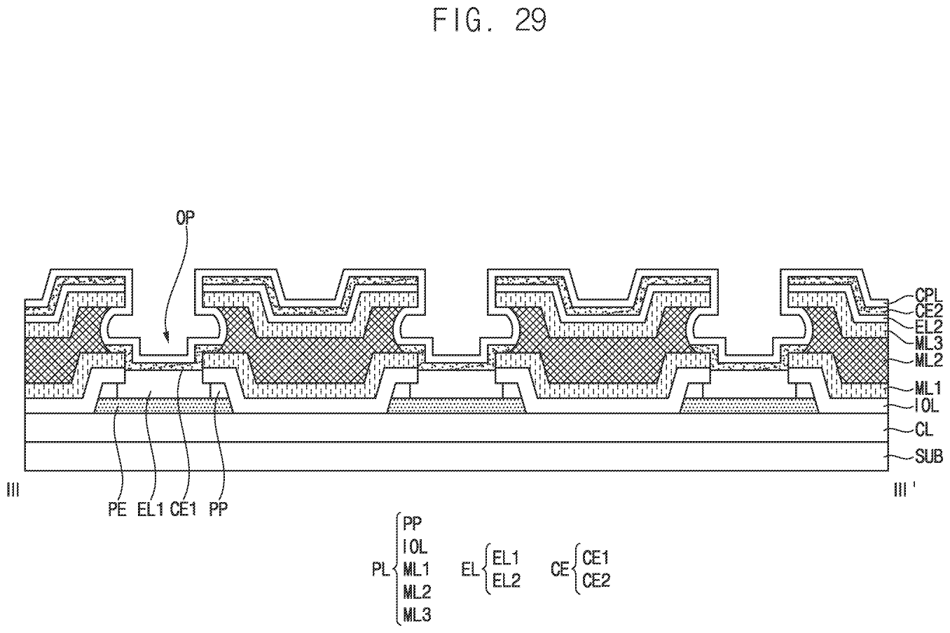

Referring to FIG. 29, the capping layer CPL may be formed on the common electrode CE, the partition layer PL and the side surface of the opening OP. In an embodiment, the capping layer CPL may extend from the upper surface of the first common electrode CE1 to the upper surface of the second common electrode CE2 along the side surface of the opening OP. The capping layer CPL may come into direct contact with the upper surface of the second common electrode CE2.

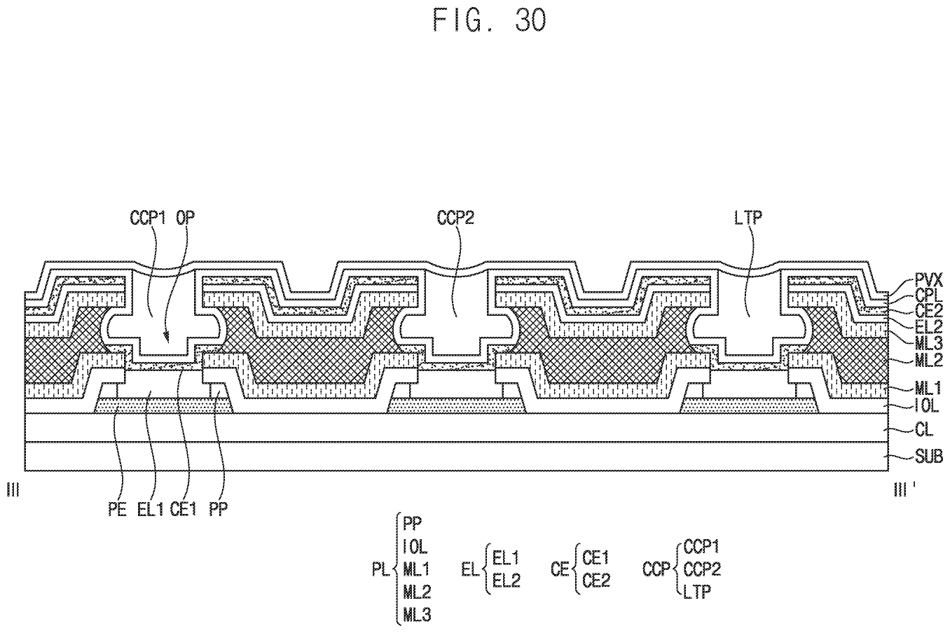

Referring to FIG. 30, the color conversion pattern CCP may be formed on the capping layer CPL in the opening OP. The passivation layer PVX may be formed on the capping layer CPL to cover the color conversion pattern CCP.

The disclosure may be applied to various display devices. In an embodiment, the disclosure is applicable to various display devices such as display devices for vehicles, ships and aircraft, portable communication devices, display devices for exhibition or information transmission, medical display devices, or the like, for example.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A display device comprising:
a substrate;
a pixel electrode disposed on the substrate;
a partition layer disposed on the substrate and defining an opening exposing at least a part of the pixel electrode;
a light-emitting layer disposed on the pixel electrode within the opening of the partition layer;
a common electrode disposed on the light-emitting layer within the opening of the partition layer;
a capping layer disposed on the common electrode and the partition layer, and surrounding a side surface of the opening of the partition layer; and
a color conversion pattern disposed on the capping layer within the opening of the partition layer.

2. The display device of claim 1, wherein the common electrode contacts the partition layer.

3. The display device of claim 1, wherein the partition layer includes:
an inorganic layer disposed on the substrate;
a first metal layer disposed on the inorganic layer; and
a second metal layer disposed on the first metal layer.

4. The display device of claim 3, wherein a side surface of the second metal layer adjacent to the opening protrudes compared to a side surface of the first metal layer adjacent to the opening.

5. The display device of claim 1, further comprising:
a pixel defining layer disposed on the partition layer and overlapping with the partition layer.

6. The display device of claim 1, wherein the light-emitting layer includes a first light-emitting layer disposed on the pixel electrode within the opening, and a second light-emitting layer disposed on the partition layer and overlapping with the partition layer, in which the first light-emitting layer and the second light-emitting layer are spaced apart from each other.

7. The display device of claim 1, wherein the capping layer extends from a first surface of the common electrode to a first surface of the partition layer along the side surface of the opening of the partition layer,
the first surface of the common electrode is opposite to a second surface of the common electrode facing the substrate, and
the first surface of the partition layer is opposite to a second surface of the partition layer facing the substrate.

8. The display device of claim 1, wherein the capping layer includes an inorganic material.

9. A method of manufacturing a display device, the method comprising:
forming a pixel electrode on a substrate;
forming a preliminary partition layer on the substrate;
forming a partition layer by defining an opening overlapping with the pixel electrode in the preliminary partition layer;
forming a light-emitting layer on the pixel electrode within the opening of the partition layer;
forming a common electrode on the light-emitting layer within the opening of the partition layer;
forming a capping layer on the common electrode, the partition layer, and a side surface of the opening of the partition layer; and
forming a color conversion pattern on the capping layer within the opening of the partition layer.

10. The method of claim 9, wherein the common electrode contacts the partition layer.

11. The method of claim 9, wherein the forming the preliminary partition layer includes:
forming a preliminary inorganic layer covering the pixel electrode on the substrate;
forming a preliminary first metal layer on the preliminary inorganic layer; and
forming a preliminary second metal layer on the preliminary first metal layer.

12. The method of claim 11, wherein the forming the partition layer includes:
defining a first sub-opening by dry etching the preliminary partition layer overlapping with the pixel electrode, and wet etching a side surface of the preliminary first metal layer exposed by the dry etching; and
defining a second sub-opening overlapping with the first sub-opening by etching the preliminary inorganic layer overlapping with the pixel electrode.

13. The method of claim 12, wherein the second sub-opening has an undercut structure.

14. The method of claim 9, wherein the capping layer extends from a first surface of the common electrode to a first surface of the partition layer along the side surface of the opening of the partition layer,
the first surface of the common electrode is opposite to a second surface of the common electrode facing the substrate, and
the first surface of the partition layer is opposite to a second surface of the partition layer facing the substrate.

15. A method of manufacturing a display device, the method comprising:
forming a pixel electrode on a substrate;
forming a preliminary partition layer on the substrate;
forming a pixel defining layer defining a first opening on the preliminary partition layer;
forming a partition layer by defining a second opening overlapping with the first opening in the preliminary partition layer;
forming a light-emitting layer on the pixel electrode within the second opening of the partition layer;
forming a common electrode on the light-emitting layer within the second opening of the partition layer;
forming a capping layer on the common electrode, the partition layer, and a side surface of the second opening of the partition layer; and
forming a color conversion pattern on the capping layer within the second opening of the partition layer.

16. The method of claim 15, wherein the common electrode contacts the partition layer.

17. The method of claim 15, wherein the forming the preliminary partition layer includes:
forming a preliminary inorganic layer covering the pixel electrode on the substrate;
forming a preliminary first metal layer on the preliminary inorganic layer; and
forming a preliminary second metal layer on the preliminary first metal layer.

18. The method of claim 17, wherein the forming the partition layer includes:
defining a first sub-opening overlapping with the first opening by dry etching the preliminary partition layer overlapping with the pixel electrode, and wet etching a side surface of the preliminary first metal layer exposed by the dry etching; and
defining a second sub-opening overlapping with the first sub-opening by etching the preliminary inorganic layer overlapping with the pixel electrode.

19. The method of claim 18, wherein the second sub-opening has an undercut structure.

20. The method of claim 15, further comprising:
removing the pixel defining layer, before the forming the capping layer.
